(19) United States
(12) Patent Application Publication
(10) Pub. No.: US 2026/0090467 A1
(43) Pub. Date: Mar. 26, 2026

(54) ELECTRONIC DEVICE

(71) Applicant: Advanced Semiconductor Engineering, Inc., Kaohsiung (TW)

(72) Inventors: Cheng-Ting CHEN, Kaohsiung (TW); Hung-Yi LIN, Kaohsiung (TW)

(73) Assignee: Advanced Semiconductor Engineering, Inc., Kaohsiung (TW)

(21) Appl. No.: 18/893,748

(22) Filed: Sep. 23, 2024

(51) Int. Cl. H01L 25/16; H01L 23/00; H01L 23/31; H01L 23/473; H01L 23/48; H01L 23/498

(52) U.S. Cl. CPC H10W 90/00; H10W 20/20; H10W 40/47; H10W 74/117; H10W 90/701; H10W 90/724

(57) ABSTRACT

An electronic device is provided. The electronic device includes a plurality of first processing units and a first transmission module. The first processing units are disposed in a data processing center. The first transmission module is configured to adjust an optical transmission direction to communicate one of the first processing units with a second processing unit through optical wireless communication.

### BACKGROUND

### 1. Technical Field

The present disclosure relates generally to an electronic device.

### 2. Description of the Related Art

Currently, data transmission between dies or modules in a large sized package is achieved by a multi-layered redistribution layer (RDL). However, long-distance data transmission between the dies suffers from serious signal attenuation and power consumption. Therefore, there is a need for improving the efficiency of long-distance data transmission between the dies or the modules in a large sized package.

### SUMMARY

In one or more arrangements, an electronic device includes a plurality of first processing units and a first transmission module. The first processing units are disposed in a data processing center. The first transmission module is configured to adjust an optical transmission direction to communicate one of the first processing units with a second processing unit through optical wireless communication.

In one or more arrangements, an electronic device includes a plurality of processing units and a circuit structure. The circuit structure includes an optical channel and a transmission module. The optical channel is configured to transmit a first signal between at least two of the processing units. The transmission module is configured to transmit a second signal through optical wireless communication.

In one or more arrangements, an electronic device includes a carrier, a plurality of electronic components, and a plurality of transmission modules. The carrier has a first surface and a second surface opposite to the first surface. The electronic components are supported by the first surface. The transmission modules are exposed from the second surface and configured to transmit a first optical signal outwardly from the electronic components through optical wireless communication.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of an electronic device in accordance with some arrangements of the present disclosure.

FIG. 1A is a top view of a portion an electronic device in accordance with some arrangements of the present disclosure.

FIG. 1B is a schematic drawing of a data processing center in accordance with some arrangements of the present disclosure.

FIG. 2 is a cross-section of an electronic device in accordance with some arrangements of the present disclosure.

FIG. 3A is a cross-section of an electronic device in accordance with some arrangements of the present disclosure.

FIG. 3B is a top view of an electronic device in accordance with some arrangements of the present disclosure.

FIG. 4 is a cross-section of an electronic device in accordance with some arrangements of the present disclosure.

FIG. 5A is a top view of an electronic device in accordance with some arrangements of the present disclosure.

FIG. 5B is a top view of an electronic device in accordance with some arrangements of the present disclosure.

FIG. 5C is a top view of an electronic device in accordance with some arrangements of the present disclosure.

FIG. 5D is a top view of a system including an electronic device in accordance with some arrangements of the present disclosure.

FIG. 6A, FIG. 6B, FIG. 6C, FIG. 6D, and FIG. 6E illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

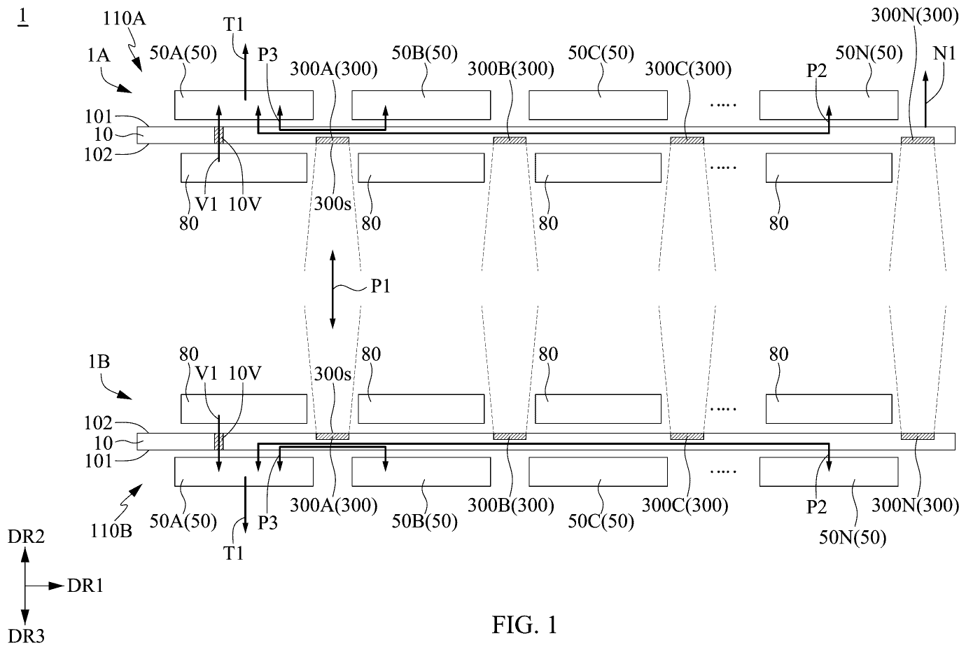

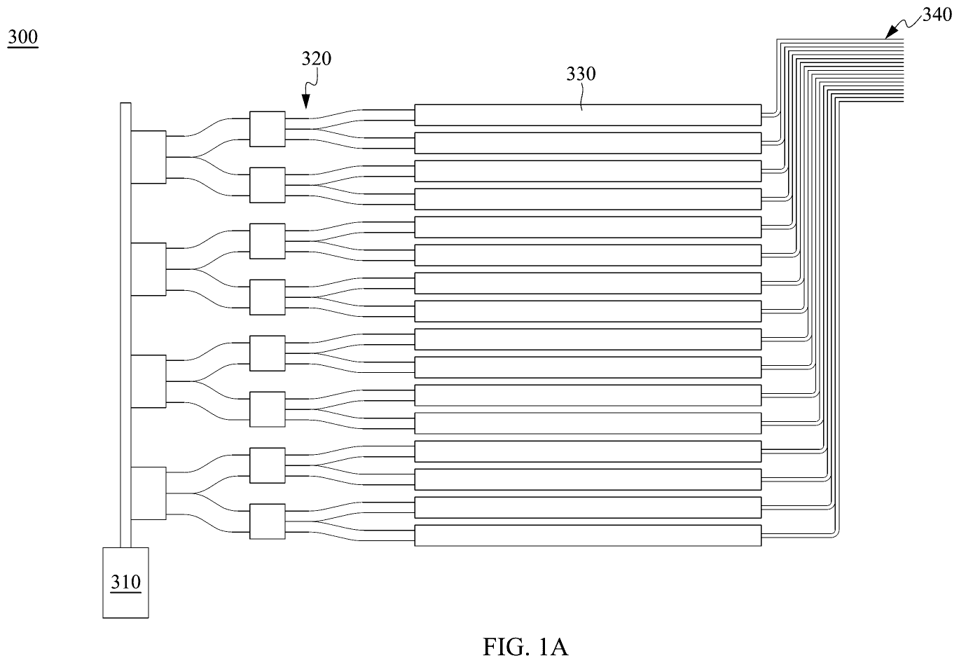

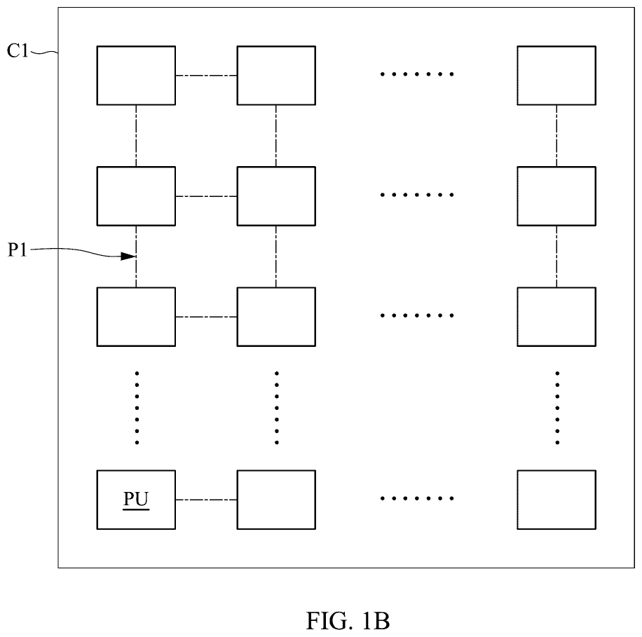

FIG. 1 is a cross-section of an electronic device 1 in accordance with some arrangements of the present disclosure. The electronic device 1 may include package structures 1A and 1B. The package structure 1A may include a circuit structure 10, a processing array 110A including a plurality of electronic components 50 (e.g., electronic components 50A to 50N), transmission modules 300 (e.g., transmission modules 300A to 300N), and power units 80. In some arrangements, the package structure 1A may be or include an extreme large scale panel (ELSP). The package structure 1B may include a circuit structure 10, a processing array 110B including a plurality of electronic components 50 (e.g., electronic components 50A to 50N), transmission modules 300 (e.g., transmission modules 300A to 300N), and power units 80. In some arrangements, the package structure 1B may be or include an ELSP. The electronic device 1 may be or include a data processing center including a great number of processing units with relatively long distances between the processing units. The electronic components 50 may be referred to as processing units described herein. The package structures 1A and 1B may be referred to as processing units described herein.

The circuit structure 10 may be referred to as a carrier. The circuit structures 10 (or the carriers) may support the electronic components 50 (or the processing array 110A and 110B). In some arrangements, the circuit structure 10 is configured to provide electrical communication (or electrical transmission) and optical communication (or optical transmission) between at least two or more of the electronic components 50. In some arrangements, the circuit structure 10 is configured to provide electrical communication between the electronic components 50 along one or more transmission paths P3 and to provide optical communication between the electronic components 50 along a transmission path P2. In some arrangements, the transmission path P2 is longer than the transmission path P3.

In some arrangements, the electronic components 50A to 50N may independently include an ASIC, an FPGA, a GPU, or the like, or a combination thereof. In some arrangements, the electronic components 50A to 50N may independently include a processing unit, such as a processing core or a processing chiplet. In some arrangements, a distance between the electronic component 50A and the electronic component 50B is less than a distance between the electronic component 50A and the electronic component 50N. The electronic components 50 may include processing components or processing units.

In some arrangements, the circuit structure 10 is configured to connect the adjacent electronic components 50 along the transmission path P3, and the circuit structure 10 is further configured to connect the electronic components 50 that are not adjacent to each other along the transmission path P2 having a greater length and a lower power consumption per unit length than the transmission path P3. The term “power consumption per unit length” used hereinafter indicates a consumption amount of power transmitted by a unit length of the transmission path, which may be also referred to as a power consumption rate. The term “power consumption” used hereinafter indicates a consumption amount of power between terminals, such as electronic components, electrodes/terminals of electronic components, and a terminal of the circuit structure and a terminal of the electronic component. In some arrangements, the relatively short communication path (i.e., the transmission path P3) between the adjacent electronic components 50 may be a millimeter (mm) level and can be implemented by an electrical path. The relatively long communication path (such as the transmission path P2) between the electronic components 50 may be under a centimeter (cm) or meter (m) level and can be implemented by an electrical path or an optical path. The optical path can provide a lower power consumption per unit length than the electrical path. In some arrangements, although the transmission path P2 has a lower power consumption per unit length, the total power consumption of the transmission path P2 may be greater than that of the transmission path P3 due to the greater length. For example, the length of the transmission path P3 connecting the adjacent electronic components 50 may be a millimeter (mm) level (e.g., about 1-4 mm), and the power consumption of the transmission path P3 may be about 0.5 pJ/bit. The length of the transmission path P2 connecting the electronic components 50 may be a centimeter (cm) or meter (m) level (e.g., about 10 cm or less), and the power consumption of the transmission path P2 may be about 2 pJ/bit.

In some arrangements, the circuit structure 10 is configured to connect the adjacent electronic components 50 along the transmission path P3, and the circuit structure 10 is further configured to connect the electronic components 50 that are not adjacent to each other along the transmission path P2 having a higher speed than the transmission path P3. When the transmission distances are the same, the signal attenuation and loss of the optical transmission (such as optical fibers) is relatively less than that of the electrical transmission (such as copper cable), since the electrical transmission is more susceptible to external interference. The speed of optical transmission is higher than that of electrical transmission. For example, the transmission rate of the optical transmission can be up to about 100 Gbps, and the transmission rate of the electrical transmission can be about 40 Gbps. Therefore, the transmission path P2 can have a higher speed than the transmission path P3. In some embodiments, the speed of the transmission path P3 may be about 50% to 75% of the speed of the transmission path P2. The speed of light may be about 200,000 km/s to about 300,000 km/s depending on the optical medium (for example, the optical fibers). The speed of electricity may be about 150,000 km/s to 297,000 km/s depending on the arrangements and elements beside the electrical transmission.

In some arrangements, the circuit structure 10 includes one or more electrical channels or electrical paths (e.g., redistribution layers; RDLs) and an optical channel or an optical path (e.g., an optical waveguide). In some arrangements, the optical channel is configured to provide signal transmission between at least two of the electronic components 50A to 50N (or the processing units). In some arrangements, the optical channel is configured to transmit a signal (also referred to as “an optical signal”) between at least two of the electronic components 50A to 50N along the transmission path P2 in a direction DR1 that is nonparallel with a normal direction N1 of the surface 101. In some arrangements, the electronic components 50A to 50N of the processing array 110A are configured to receive power in a direction DR2 different from the direction DR1. In some arrangements, the electronic components 50A to 50N of the processing array 110B are configured to receive power in a direction DR3 different from the direction DR1. In some arrangements, the electrical channel is configured to transmit a signal (also referred to as “an electrical signal”) between two adjacent ones of the electronic components 50A to 50N through the transmission path P3 in a direction that is nonparallel with (e.g., perpendicular to) the normal direction N1 of the surface 101. In some arrangements, the circuit structure 10 further includes at least a conductive via 10V extending between the surface 101 and the surface 102. In some arrangements, each of the processing arrays 110A and 110B may be constituted by the electronic components 50A to 50N. The circuit structure 10 may be or include an extremely large scale panel (ELSP), e.g., a panel with a size of 300 mm×300 mm, 600 mm×600 mm, or greater.

In some arrangements, the power units 80 (also referred to as “the power modules”) are configured to transmit or provide power to the electronic components 50. In some arrangements, the power units 80 are configured to transmit or provide power to the corresponding electronic components 50 (or the processing units). For example, each of the power units 80 may be configured to transmit power to each of the corresponding electronic components 50A to 50N. In some arrangements, the power units 80 and the electronic components 50A to 50N are located at different surfaces. In some arrangements, the electronic components 50A to 50N are located at or disposed over the surface 101 of the circuit structure 10 (or the carrier), and the power units 80 are located at or disposed over the surface 102 opposite to the surface 101 of the circuit structure 10 (or the carrier). In some arrangements, the power units 80 and the electronic components 50A to 50N are disposed at opposite sides of the optical channel.

In some arrangements, the transmission modules 300 are configured to adjust one or more optical transmission paths through optical wireless communication. In some arrangements, the transmission module 300 is configured to adjust an optical transmission direction to communicate a processing unit with another processing unit through optical wireless communication. In some embodiments, the transmission module 300 is configured to adjust a transmission direction of an optical signal transmitted from a processing unit to another processing unit along one or more transmission paths P1 through optical wireless communication. In some arrangements, the transmission module 300 includes an optical phase array (OPA) unit configured to receive or transmit an optical signal. In some arrangements, the transmission path P1 may be configured to perform optical communication over a distance over about 10 cm.

In some arrangements, the transmission module 300 is configured to adjust an optical transmission direction to communicate an electronic component 50 (or a processing unit) with another electronic component 50 (or another processing unit) along a transmission path P1 through optical wireless communication. In some arrangements, the transmission modules 300 (e.g., the transmission modules 300A to 300N) are configured to adjust optical transmission directions to communicate corresponding electronic components 50A to 50N with another one of the electronic components 50A to 50N through optical wireless communication. In some arrangements, the transmission modules 300A to 300N and the corresponding electronic components 50A to 50N (or the processing units) are disposed on opposite sides of the circuit structure 10 (or the carrier).

In some arrangements, each of the transmission modules 300A to 300N may be configured to adjust an optical transmission direction to communicate each of the corresponding electronic components 50A to 50N with another one of the electronic components 50A to 50N through optical wireless communication. For example, the transmission module 300A of the processing array 110A is configured to adjust an optical transmission direction to communicate the electronic component 50A of the processing array 110A to one of the electronic components 50A to 50N of the processing array 110B along the transmission path P1 through optical wireless communication. For example, the transmission module 300B of the processing array 110A is configured to adjust an optical transmission direction to communicate the electronic component 50B of the processing array 110A to one of the electronic components 50A to 50N of the processing array 110B along the transmission path P1 through optical wireless communication. For example, the transmission module 300C of the processing array 110A is configured to adjust an optical transmission direction to communicate the electronic component 50C of the processing array 110A to one of the electronic components 50A to 50N of the processing array 110B along the transmission path P1 through optical wireless communication. The transmission path P1 (or the optical transmission direction) may be non-parallel to the transmission path P2.

In some arrangements, one or more of the transmission modules 300 are configured to transmit one or more signals (e.g., optical signals) through optical wireless communication. In some arrangements, one or more of the transmission modules 300 are configured to transmit one or more signals (e.g., optical signals) outwardly from the electronic components 50 (or the processing units) through optical wireless communication. In some arrangements, the transmission module 300 is configured to transmit a signal (e.g., an optical signal) outwardly from the processing array 110A or 110B through optical wireless communication. For example, the transmission module 300A of the package structure 1A is configured to transmit a signal (or an optical signal) outwardly from the processing array 110A through optical wireless communication. For example, the transmission module 300A of the package structure 1B is configured to receive a signal (or an optical signal) from the transmission module 300A of the package structure 1A and transmit the signal (or the optical signal) to the processing unit 50A of the package structure 1B. In some arrangements, the transmission module 300 is configured to transmit a signal (or an optical signal) along the transmission path P1 in a direction different from the direction DR1 in which the optical channel is configured to transmit a signal. In some arrangements, the transmission module 300 is configured to transmit a signal (or an optical signal) in a direction (e.g., the direction DR2 or DR3) substantially perpendicular to the direction DR1 in which the optical channel is configured to transmit a signal. For example, the transmission module 300A of the package structure 1A is configured to transmit a signal (or an optical signal) in a direction DR3 (e.g., an optical transmission direction) substantially perpendicular to the direction DR1 in which the optical channel is configured to transmit a signal. For example, the transmission module 300A of the package structure 1B is configured to transmit a signal (or an optical signal) in a direction DR2 (e.g., an optical transmission direction) substantially perpendicular to the direction DR1 in which the optical channel is configured to transmit a signal.

In some arrangements, one of the transmission modules 300 is configured to receive an optical signal from another one of the transmission modules 300 through the optical wireless communication. In some embodiments, the two transmission modules 300 face to each other. For example, the transmission module 300A of the processing array 110A is configured to receive an optical signal from one of the transmission modules 300A to 300N of the processing array 110B along the transmission path P1 through the optical wireless communication.

In some arrangements, one or more transmission modules 300 may be disposed between at least two of the power units 80. In some embodiments, the transmission modules 300 are exposed by the power units 80. In some embodiments, the transmission modules 300 are exposed from the surface 102 of the circuit structure 10. In some arrangements, the transmission modules 300 are embedded in the circuit structure 10 and exposed by the surface 102. In some arrangements, the transmission modules 300 may be discrete elements disposed on the surface 102 of the circuit structure 10. In some arrangements, the power units 80 in the package structure 1A are configured to transmit power to the electronic components 50 (or the processing units) in a direction DR2 different from the direction DR1 and the optical transmission direction (e.g., the direction DR3). In some arrangements, the power units 80 in the package structure 1B are configured to transmit power to the electronic components 50 (or the processing units) in a direction DR3 different from the direction DR1 and the optical transmission direction (e.g., the direction DR2). The direction DR2 may be substantially parallel to or opposite to the direction DR3.

In some arrangements, the transmission modules 300 include a plurality of circuits in the circuit structure 10 (or the carrier) and a plurality of light emitting areas 300s exposed by the surface 102. In some embodiments, the light emitting areas 300s of the transmission modules 300 are between the power units 80.

In some arrangements, the electronic device 1 may further include a power path V1 (also referred to as “a power channel”) configured to deliver power through the surface 101 to at least one of the electronic components 50A to 50N in a direction (e.g., the direction DR2 or DR3) different from the direction DR1. In some arrangements, the direction DR2 and direction DR3 are substantially in parallel with the normal direction N1 of the surface 101. The power path V1 may be or include an electrical channel (e.g., the conductive via 10V). The power path V1 may be non-parallel to the transmission path P1 (or the optical transmission direction). The transmission path P1 may vary within a range defined by the light emitting angle or the light receiving angle of the transmission modules 300.

In some arrangements, the electronic device 1 may further include a thermal channel T1 configured to transfer heat outwardly from at least one of the electronic components 50A to 50N in a direction (e.g., the direction DR2 or DR3) without intersecting with the surface 101. In some arrangements, the thermal channel T1 is configured to transfer or dissipate heat in a heat dissipation direction (e.g., the direction DR2 or DR3) from the circuit structure 10 (or the carrier) toward the electronic components 50 (or the processing units). In some arrangements, the thermal channel T1 extends outwardly from least one of the electronic components 50A to 50N without intersecting with the surface 101. In some embodiments, the optical transmission direction (e.g., the direction DR2 or DR3) is substantially parallel to the heat dissipation direction (e.g., the direction DR2 or DR3). In some embodiments, the optical transmission direction (e.g., the direction DR2 or DR3) is substantially opposite to the heat dissipation direction (e.g., the direction DR2 or DR3). For example, the thermal channel T1 in the package structure 1A is configured to transfer heat in a heat dissipation direction (e.g., the direction DR2) substantially opposite to the optical transmission direction (e.g., the direction DR3) in which the transmission module 300A is configured to transmit a signal. For example, the thermal channel T1 in the package structure 1B is configured to transfer heat in a heat dissipation direction (e.g., the direction DR3) substantially opposite to the optical transmission direction (e.g., the direction DR2) in which the transmission module 300A is configured to transmit a signal. The thermal channel T1 may be non-parallel to the transmission path P1 (or the optical transmission direction). The transmission path P1 may vary within a range defined by the light emitting angle or the light receiving angle of the transmission modules 300.

FIG. 1A is a top view of a portion an electronic device 1 in accordance with some arrangements of the present disclosure. In some arrangements, FIG. 1A is a top view of the transmission module 300 in accordance with some arrangements of the present disclosure.

The transmission module 300 may include a free space optical (FSO) transceiver, a FSO receiver, or a combination thereof. In some arrangements, the transmission module 300 includes an optical source 310, an optical splitter 320, an optical phase shifter 330, and an optical grating 340. The optical source 310, the optical splitter 320, the optical phase shifter 330, and the optical grating 340 may collectively form an FSO transceiver. The transmission module 300 may further include a photodetector as a FSO receiver.

The optical source 310 may be or include a laser device. The optical splitter 320 may be optically coupled to the optical source 310 and include a plurality of optical branches configured to split light or an optical signal provided from the optical source 310 into a plurality of light beams or optical signals. The optical phase shifter 330 may be optically coupled to the optical splitter 320 and configured to adjust the phase of the optical signals transmitted from the optical splitter 320. The optical phase shitter 330 may include a PIN diode. The phase of the optical signal may be adjusted by varying the bias applied to the PIN diode. The optical grating 340 may be optically coupled to the optical phase shifter 330 and configured to emit the output optical signal. The transmission direction of the output optical signal may be determined by the phase differences between the split optical signals controlled by the optical phase shifter 330 and the patterns of the optical grating 340. The optical source 310, the optical splitter 320, the optical phase shifter 330, and the optical grating 340 may be formed in or integrated to the circuit structure 10, and the light emitting areas 300s may be connected to the optical grating 340 and exposed by the surface 102 of the circuit structure 10. In some arrangements, the light emitting areas 300s may be connected to the photodetector and exposed by the surface 102 of the circuit structure 10. The optical source 310, the optical splitter 320, and the optical phase shifter 330 may be formed within the circuit structure 10. Circuits that are electrically connected to the optical source 310, the optical splitter 320, and/or the optical phase shifter 330 may be further integrated into the circuit structure 10.

FIG. 1B is a schematic drawing of a data processing center C1 in accordance with some arrangements of the present disclosure. The data processing center C1 may include a plurality of processing units PU optically coupled to each other through optical wireless communication.

In some arrangements, the electronic device 1 illustrated in FIG. 1 may include a plurality of electronic components 50 (also referred to as “processing units”) disposed in the data processing center C1. In some arrangements, the electronic device 1 illustrated in FIG. 1 may include a plurality of package structures 1A and 1B (also referred to as “processing units”) disposed in the data processing center C1. The processing units PU may optically communicate with each other through optical wireless communication along one or more transmission paths P1.

Currently, large scale panels (LSPs) or extreme large scale panels (ELSPs) usually include multi-layered conductive interconnection structures (e.g., RDLs) for transmitting electrical signals. However, long distance transmission of electrical signals between packages through RDLs may lead to issues of signal attenuation, high power consumption, and low power efficiency. In addition, discrete input/output (I/O) terminals (e.g., fiber array units) and connectors are required for transmitting electrical signals through RDLs, the volume and the size of packages may increase, and the cost may be increased as well.

According to some arrangements of the present disclosure, the processing units in a data processing center are communicated with each other through optical wireless communication. The transmission rate of the optical wireless communication can be up to 100 Gbps or higher, which is even higher than conventional electrical wireless communication technique or optical communication. Therefore, an extremely high speed signal transmission between the processing units that are separated from each other by several meters or more can be achieved. In addition, optical wireless communication does not require wiring structures, and thus in addition to high speed transmission, optical wireless communication can achieve highly secure transmission because optical signals are difficult to eavesdrop on or interfere with. Moreover, discrete I/O terminals and connectors are not required for optical wireless communication, and thus the volume and the size of the package structures 1A and 1B (or the electronic device 1) can be reduced, the cost is reduced, and energy savings and environmental protection can be achieved as well, as it does not require wire transmission that consumes a large amount of power to transmit electrical signals. Furthermore, optical wireless communication is free from electromagnetic interferences, and thus the electronic device 1 can be substantially free from electromagnetic interferences and thus be used in an environment that requires high stability.

Moreover, according to some arrangements of the present disclosure, the processing units are communicated with each other through optical wireless communication using one or more transmission modules 300 configured to adjust optical transmission directions. The optical wireless transmission paths can be switched between different pairs of processing units simply by adjusting optical transmission directions of optical signals or optical signals received or emitted by the transmission modules 300. Therefore, the optical wireless transmission paths can be reconfigurable. In addition, the optical wireless transmission paths can overlap spatially without occupying physical space, and the optical wireless transmission paths can be switched through the transmission modules 300, thus multiple optical wireless transmission paths can share portions of each other's physical space. As a result, the designs of the optical wireless transmission paths are not constrained by the arrangements of physical layers of wiring structures in space.

Furthermore, according to some arrangements of the present disclosure, one or more transmission modules 300 are disposed between at least two of the power units 80. As such, the transmission modules 300 can be disposed within the space between the power units 80 without occupying extra spaces or areas of the electronic device 1. Therefore, the size of the electronic device 1 can be prevented from being increased undesirably.

Moreover, according to some arrangements of the present disclosure, the optical source 310, the optical splitter 320, the optical phase shifter 330, and the optical grating 340 may be formed in or integrated to the circuit structure 10. As such, the manufacturing process for the transmission modules 300 can be integrated in the manufacturing process for forming the circuit structure 10. Therefore, the process for the transmission modules 300 is compatible with the semiconductor manufacturing process of the circuit structure 10, and thus the manufacturing process can be simplified, and the cost can be reduced.

In addition, according to some arrangements of the present disclosure, the transmission modules 300 or the light emitting surfaces 300s are exposed by a bottom surface (e.g., the surface 102) of the package structure 1A or 1B. The bottom surface of the package structure 1A or 1B has an area greater than that of lateral surfaces of the package structure 1A or 1B. Therefore, more transmission modules 300 can be disposed on or exposed by the bottom surface than the lateral surface of the package structure, and a higher light emitting area can be obtained from the bottom surface than the lateral surface of the package structure. Accordingly, optical coupling efficiency is improve.

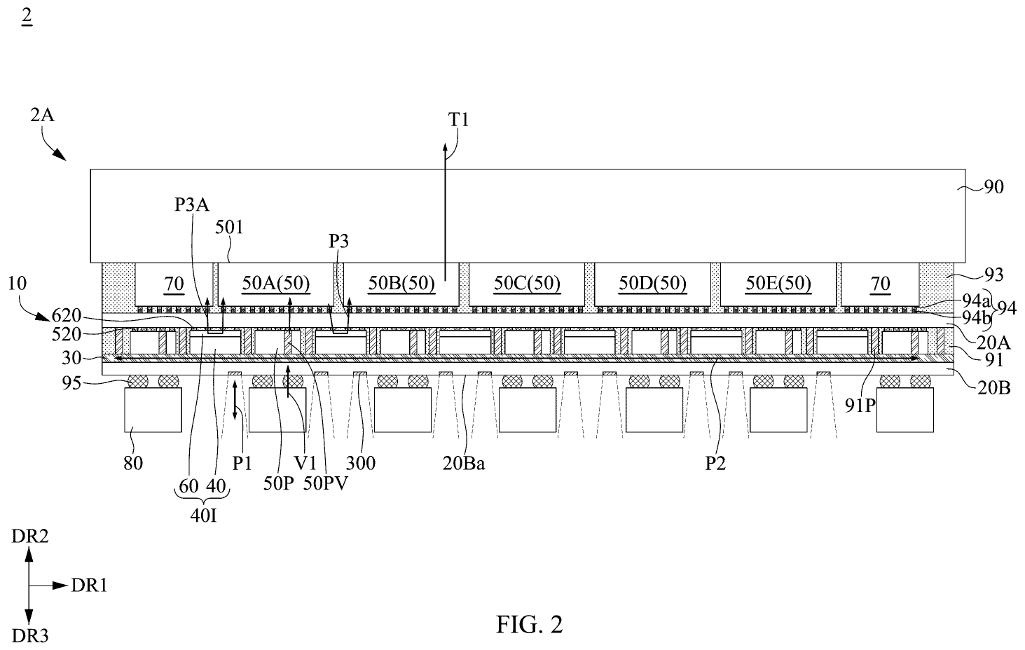

FIG. 2 is a cross-section of an electronic device 2 in accordance with some arrangements of the present disclosure. The electronic device 2 is similar to the electronic device 1 in FIG. 1, and the differences therebetween are described as follows.

In some arrangements, the electronic device 2 includes a package structure 2A further including a bridge components 40I, electronic components 50P, storage components 70, a cooling device 90, encapsulants 91 and 93, pillars 91P, and connection elements 94 and 95. The electronic device 2 may include a plurality of the package structures 2A. The electronic components 50 may be referred to as processing units described herein. The package structure 2A may be referred to as a processing unit described herein. The electronic device 2 may be or include a data processing center including a great number of processing units with relatively long distances between the processing units.

In some arrangements, the circuit structure 10 includes circuits 20A, 20B, and 30. The circuits 20A and 20B may be referred to as circuit layers, redistribution layers (RDLs), or the like. The circuit 30 may be referred to as an optical waveguide, an optical channel, an optical path, or the like.

In some arrangements, the circuit 20A (also referred to as an electrical channel) is disposed between the circuit 30 and the electronic components 50 and configured to connect at least two of the electronic components 50 along the transmission path P3. In some arrangements, the circuit 20A (or the electrical channel) is configured to transmit an electrical signal along the transmission path P3. The circuit 20A may include a dielectric layer and a conductive structure (not shown in FIG. 2) formed in the dielectric layer. The conductive structure may include an interconnection structure (e.g., a redistribution layer (RDL)), which may include such as a plurality of conductive traces and/or a plurality of conductive vias. The interconnection structure may be or include circuit layers. In some arrangements, the transmission path P3 passes a portion of the conductive structure of the circuit 20A to electrically connect to the electronic component 50 to provide electrical communication or electrical connection. The transmission path P3 may be an electrical path.

In some arrangements, the circuit 30 (or the optical channel) is configured to connect the electronic components 50 along the transmission path P2. In some arrangements, the circuit 30 vertically overlaps two or more of the electronic components 50. In some arrangements, the circuit 30 includes an optical channel or an optical path. In some arrangements, the circuit 30 includes an optical waveguide. The circuit 30 may be formed of or include an optical waveguide material, e.g., a polymer material (e.g., a polymer waveguide), silicon nitride, silicon oxide, or other suitable materials. In some arrangements, the circuit 30 includes one or more optical fibers. In some arrangements, the circuit 30 includes a glass substrate including glass modification lines having a refractive index higher than that of the glass substrate and serving as the optical channel. In some arrangements, the transmission path P2 passes a portion of the circuit 30 (or the optical waveguide) to provide optical communication or optical connection. In some embodiments, the circuit 30 (or the optical channel) is configured to transmit an optical signal between at least two of the electronic components 50 along the transmission path P2 in a direction DR1 substantially parallel to the surface 101. In some arrangements, the transmission path P3 is shorter than the transmission path P2.

The circuit 20B may support the bridge components 40I. In some arrangements, the bridge components 40I are disposed between the circuit 20A and the circuit 20B. The circuit 20B may include a dielectric layer and a conductive structure (not shown in FIG. 2) formed in the dielectric layer. The conductive structure may include an interconnection structure (e.g., a RDL), which may include such as a plurality of conductive traces and/or a plurality of conductive vias. The interconnection structure may be or include circuit layers. In some arrangements, the circuit 30 may be formed in the dielectric layer of the circuit 20B. In some arrangements, a top surface of the circuit 30 may be substantially coplanar or aligned with a top surface of the circuit 20B. In some arrangements, the circuit 20B may be replaced by a substrate without any conductive structure formed therein, and the substrate is configured to support the components/element there above. In some arrangements, the transmission modules 300 are embedded in the circuit 20B and exposed by a surface 20Ba of the circuit 20B. In some arrangements, the transmission modules 300 may be discrete elements disposed on the surface 20Ba of the circuit 20B.

In some arrangements, the electronic components 50P are disposed between the bridge components 40I. The electronic component 50P may be or include a passive component, e.g., a capacitor, an inductor, or other suitable passive component. In some arrangements, the electronic component 50P is or includes a power regulating element (e.g., a voltage regulating module (VRM)). In some arrangements, the power units 80 are disposed under the circuit 20B and configured to provide power to the electronic components 50 through the power regulating elements (e.g., the electronic components 50P). In some arrangements, the electronic component 50P may include at least one conductive via 50PV extending between a top surface and a bottom surface of the electronic component 50P, the power path V1 passes the circuit 20B and the power regulating element (e.g., the conductive via 50PV of the electronic components 50P). In some arrangements, the electronic component 50P includes connection elements 520 electrically connected the circuit 20A to the conductive via 50PV.

In some arrangements, the bridge component 40I is configured to provide a photoelectric conversion at the transmission path P2 and provide electrical communication between adjacent electronic components 50. In some embodiments, the bridge component 40I includes a bridge element 60 and an optical engine 40 integrated with the optical engine 40. The bridge element 60 is configured to electrically connect the one of the electronic components (e.g., electronic components 50A, 50B, 50C, 50D, and 50E) to the storage component 70. The optical engine 40 is configured to convert an electrical signal from the one of the electronic components 50A, 50B, 50C, 50D, and 50E to an optical signal. In some arrangements, the bridge element 60 is configured to provide the electrical communication between the electronic component 50A and the electronic component 50B, and the optical engine 40 is configured to provide the photoelectric conversion for the optical communication between the electronic component 50A and the electronic component 50E. The optical engine 40 may include a photonic component and an electronic component. The photonic component may be or include a photonic integrated circuit (PIC), and the electronic component may be or include an electronic integrated circuit (EIC). In some arrangements, the bridge element 60 may be or include a patterned conductive layer or a patterned conductive trace formed on a top surface of the optical engine 40. In some arrangements, the bridge element 60 may be or include a bridge die formed on a top surface of the optical engine 40, and bridge die includes a patterned conductive layer or a patterned conductive trace formed on a top surface of a substrate layer of the bridge die. In some arrangements, the bridge element 60 includes connection elements 620 electrically connected to the circuit 20A. In some arrangements, the circuit 20B includes an optical channel (e.g., the circuit 30) configured to optically couple to the bridge components 40I and provide an optical communication between the bridge components 40I.

The storage component 70 may include memory components (or memory units), e.g., HBM. In some arrangements, the circuit 20A is configured to provide electrical communication between the electronic components 50 and the storage component 70 along one or more transmission paths P3A. In some arrangements, at least one of the electronic components 50 is configured to access the storage component 70 through the bridge element 60 along the transmission path P3.

In some arrangements, the power units 80 are connected to the circuit 20B through the connection elements 95. The connection elements 95 may be or include C4 bumps. In some arrangements, the power units 80 are configured to provide power to the electronic components 50 through the pillars 91P between the bridge components 40I. In some arrangements, each of the power units 80 is under and configured to provide a modulated power to each of the electronic components 50. The power modules 80 may be or include voltage regulation modules (VRMs).

In some arrangements, the encapsulant 91 encapsulates the bridge components 40I, the electronic component 50P, and the pillars 91P. In some arrangements, the encapsulant 91 further encapsulates the connection elements 520 and 620. In some arrangements, the pillars 91P may be formed of or include a conductive material, e.g., metal, such as copper (Cu). In some arrangements, at least one of the pillars 91P electrically connects the circuit 20A to the circuit 20B. In some arrangements, some of the pillars 91P may serve as thermal pipes for dissipating heat. The thermal pipes may be disposed between the bridge components 40I.

In some arrangements, the connection elements 94 electrically connect the electronic components 50 to the circuit 20A. In some arrangements, the connection elements 94 may be or include micro-bumps. Each of the connection elements 94 may include portions 94a and 94b. The portion 94a may be a conductive pad or stud, and the portion 94b may be a solder bump. In some arrangements, the encapsulant 93 encapsulates the electronic component 50A to 50E and 70 and the connection elements 94.

The cooling device 90 may be disposed over the electronic components 50. In some arrangements, the cooling device 90 contacts the electronic components 50. The cooling device 90 is configured to dissipate heat from the electronic components 50. The cooling device 90 may be or include a water-cooling device (e.g., a water cooling plate), an air-cooling device, or a combination thereof. In some arrangements, the cooling device 90 is disposed on the encapsulant 93 and contacting the exposed surfaces 501 of the electronic components 50.

In some arrangements, each of the electronic components 50A, 50B, 50C, 50D, and 50E is correspond to two transmission modules 300 disposed thereunder. In some arrangements, the two transmission modules 300 may include a FSO transceiver and a FSO receiver. In some arrangements, each of the transmission modules 300 may include a FSO transceiver and a FSO receiver integrated into the transmission module 300.

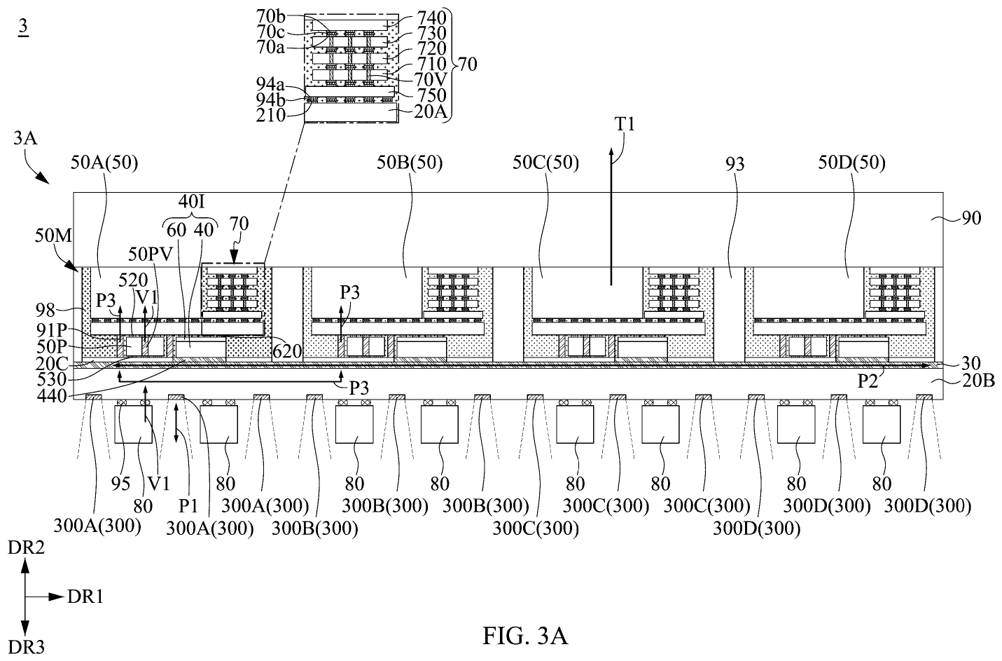

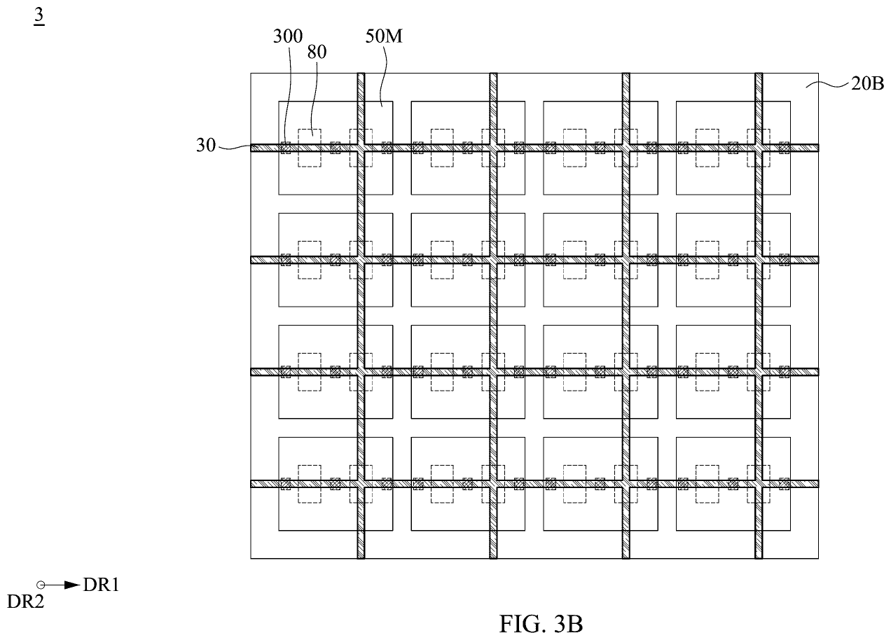

FIG. 3A is a cross-section of an electronic device 3 in accordance with some arrangements of the present disclosure. FIG. 3B is a top view of an electronic device 3 in accordance with some arrangements of the present disclosure. In some arrangements, FIG. 3B shows a top view of the structure illustrated in FIG. 3A. The electronic device 3 is similar to the electronic device 2 in FIG. 2, and the differences therebetween are described as follows.

In some arrangements, the electronic device 3 includes a package structure 3A further including a plurality of processing modules 50M. The electronic device 3 may include a plurality of the package structures 3A. In some arrangements, the encapsulant 93 encapsulates the processing modules 50M. The electronic components 50 may be referred to as processing units described herein. The processing modules 50M may be referred to as processing units described herein. The package structure 3A may be referred to as a processing unit described herein. The electronic device 3 may be or include a data processing center including a great number of processing units with relatively long distances between the processing units.

In some embodiments, the processing module 50M includes circuits 20A and 20C, a bridge component 40I, electronic components 50 and 50P, a storage component 70, at least a pillar 91P, and an encapsulant 98. The bridge component 40I may be referred to as a bridge element. The electronic component 50 may be or include a processing chip. The storage component 70 may be or include a storage module.

In some arrangements, the circuit layer 20A electrically connects the electronic component 50 (or the processing chip) to the storage component 70 (or the storage module). In some arrangements, the bridge component 40I electrically connects the electronic component 50 to the storage component 70. In some arrangements, the bridge component 40I is configured to provide electrical communication between the electronic component 50 (or the processing chip) and the storage component 70 (or the storage module) through the circuit layer 20A. In some arrangements, the pillar 91P electrically connects the circuit 20A to the circuit 20C. In some arrangements, the bridge component 40I further includes an optical conductive structure 440 optically coupling the optical engine 40 to the circuit 30 (or the optical channel). In some arrangements, the encapsulant 98 encapsulates the circuits 20A and 20C, the bridge component 40I, the electronic components 50 and 50P, the storage component 70, and the pillar 91P.

In some arrangements, the storage component 70 includes a plurality of memory dies 710, 720, 730, and 740 and a logic die 750 stacked over each other and connection elements 70c electrically connecting the memory dies 710, 720, 730, and 740 and the logic die 750. In some arrangements, conductive pads 70b of the memory die 740 electrically connect to conductive pads 70a of the memory die 730 through the connection elements 70c. In some arrangements, conductive pads 70b of the memory die 730 electrically connect to conductive pads 70a of the memory die 720 through the connection elements 70c. In some arrangements, conductive pads 70b of the memory die 720 electrically connect to conductive pads 70a of the memory die 710 through the connection elements 70c. In some arrangements, conductive pads 70b of the memory die 710 electrically connect to conductive pads 70a of the logic die 750 through the connection elements 70c. In some arrangements, portions 94a and 94b of the connection elements 94 electrically connect the logic die 750 to conductive pads 210a of the circuit 20A.

Referring to FIG. 3B, in some arrangements, the circuit 30 includes an optical mesh network. In some arrangements, the circuit 30 includes a grid structure. In some arrangements, the circuit 30 includes a single-layered grid structure. In some arrangements, the circuit 30 includes an optical waveguide network (or an optical grid structure) including a plurality of waveguides crossing each other. In some arrangements, the intersections of the waveguides are disposed under the optical engines 40. In some arrangements, the intersections are formed of two waveguides crossing-over and stacked on each other. The network of intersections formed from crossed-over and stacked waveguides may be referred to as an optical mesh network. In some arrangements, the intersections are formed of waveguides directly connected to each other and/or formed integrally in a single layer. The network of intersections formed in a single layer may be referred to as a single-layered optical grid structure. In some arrangements, each of the intersections of the waveguides is disposed under and optically coupled to the optical engine (not shown in FIG. 3B) that connects to a corresponding one of the processing modules 50M to receive an optical signal from or transmit an optical signal to the optical engine. In some arrangements, the optical waveguide network of the circuit 30 may overlap the transmission modules 300 and the power units 80 from a top view perspective.

In some arrangements, each of the electronic components 50A, 50B, 50C, and 50D, is correspond to three transmission modules 300 disposed thereunder. In some arrangements, the three transmission modules 300 may include two FSO transceiver and one FSO receiver or one FSO transceiver and two FSO receivers. In some arrangements, each of the transmission modules 300 may include a FSO transceiver and a FSO receiver integrated into the transmission module 300.

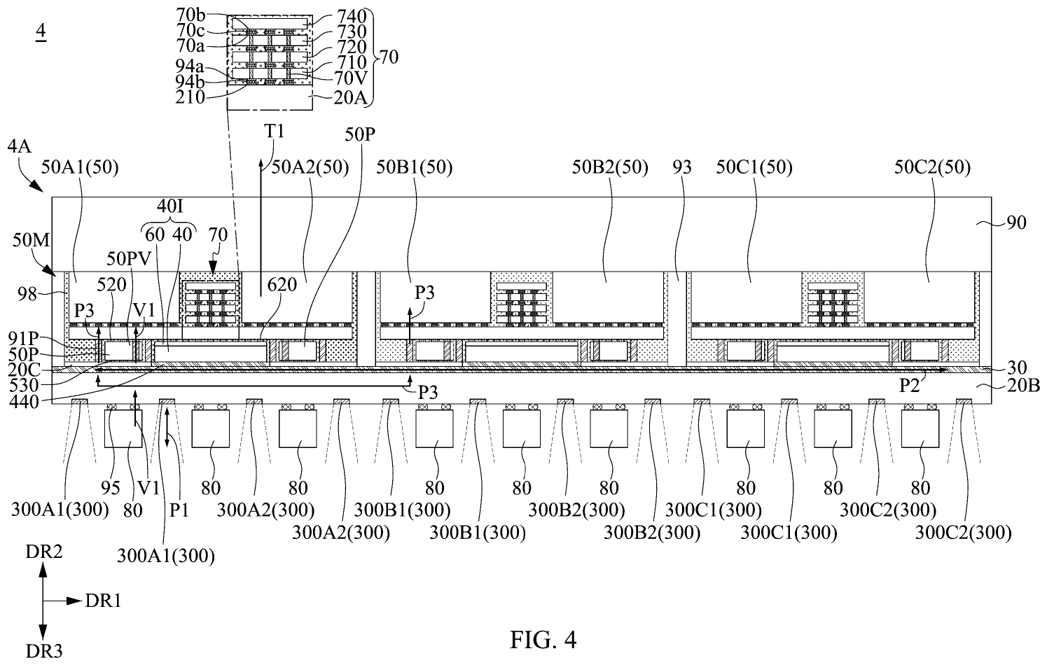

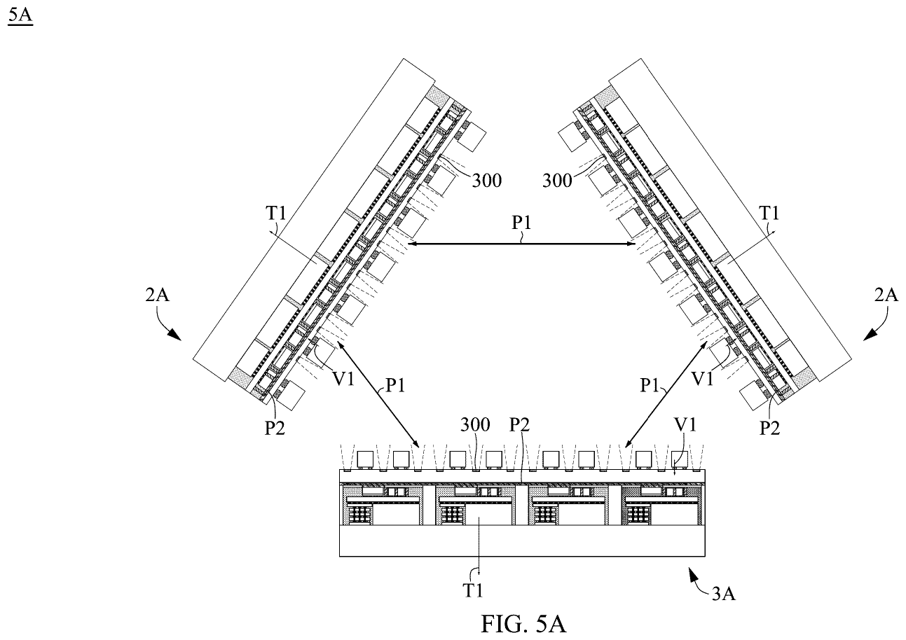

FIG. 4 is a cross-section of an electronic device 4 in accordance with some arrangements of the present disclosure. The electronic device 4 is similar to the electronic device 3 in FIGS. 3A and 3B, and the differences therebetween are described as follows.

In some arrangements, the electronic device 4 includes a package structure 4A including a plurality of processing modules 50M. The electronic device 4 may include a plurality of the package structures 4A. The electronic components 50 may be referred to as processing units described herein. The processing modules 50M may be referred to as processing units described herein. The package structure 3A may be referred to as a processing unit described herein. The electronic device 4 may be or include a data processing center including a great number of processing units with relatively long distances between the processing units.

In some embodiments, the processing module 50M includes circuits 20A and 20C, a bridge component 40I, electronic components 50A1, 50A2, and 50P, a storage component 70, pillars 91P, and an encapsulant 98. The bridge component 40I may be referred to as a bridge element. The electronic component 50 may be or include a processing chip. The storage component 70 may be or include a storage module.

In some arrangements, the storage component 70 includes a plurality of memory dies 710, 720, 730, and 740 stacked over each other and connection elements 70c electrically connecting the memory dies 710, 720, 730, and 740. The storage component 70 does not include a logic die. In some arrangements, the bridge element 60 of the bridge component 40I includes a control logic circuit configured to control access to the storage module 70. In some arrangements, the control logic circuit is configured to generate control signals to perform a write operation and/or a read operation.

In some arrangements, a wafer node of the bridge element 60 (or the control logic circuit) is less than or smaller than a wafer node of the memory dies 710, 720, 730, and 740. A wafer node of the bridge element 60 (or the control logic circuit) may lead a wafer node of the memory dies 710, 720, 730, and 740 by one or more generations. For example, the bridge element 60 (or the control logic circuit) may be a 7 nm or less node wafer, and the memory dies may be a 14 nm or more node wafer, such as a 16 nm or more node wafer, a 20 nm or more node wafer, or greater.

In some arrangements, the bridge element 60 is configured to provide the electrical communication between the electronic components in the same processing module 50M. For example, the bridge element 60 may be configured to provide the electrical communication between the electronic components 50A1 and 50A2. In some arrangements, the bridge element 60 is configured to control access to the memory dies of the storage component 70. In some arrangements, the electronic component 50A1 is configured to access the memory dies of the storage component 70 by sending a command signal to the bridge element 60 (or the control logic circuit) which is configured to generate a control signal in response to the command signal to access the memory dies of the storage component 70. In some arrangements, the electronic component 50A2 is configured to access the memory dies of the storage component 70 by sending a command signal to the bridge element 60 (or the control logic circuit) which is configured to generate a control signal in response to the command signal to access the memory dies of the storage component 70.

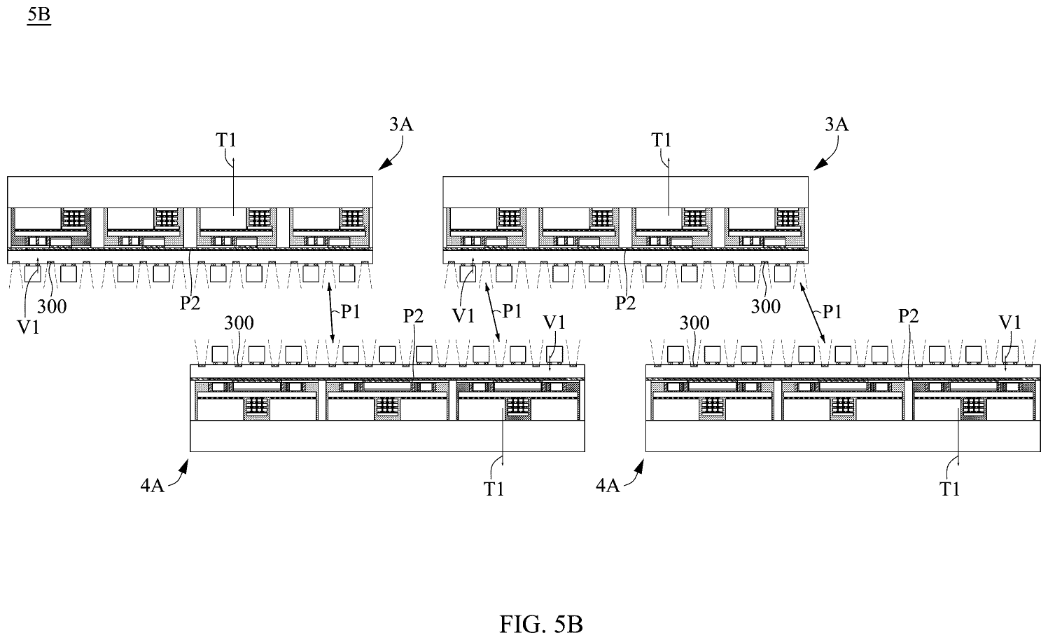

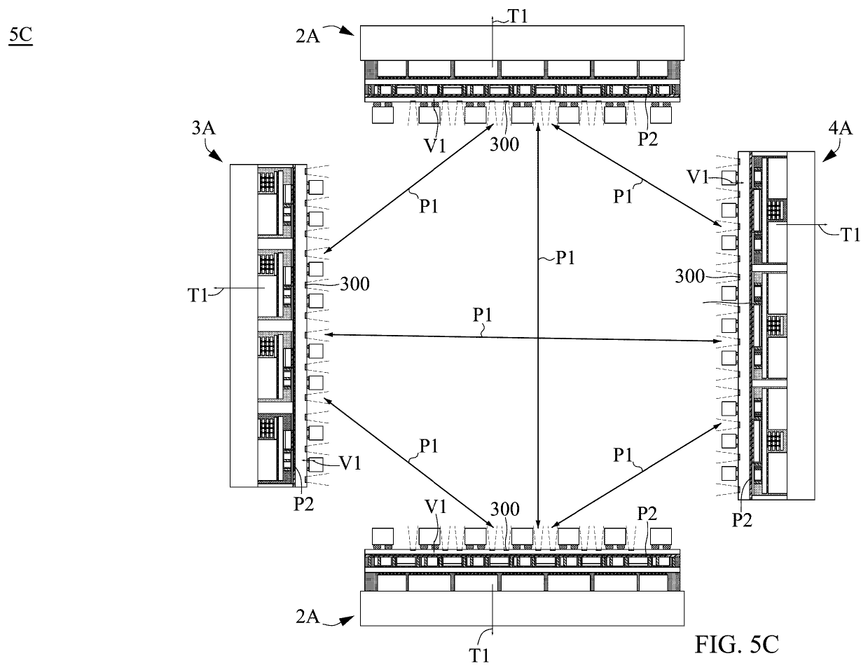

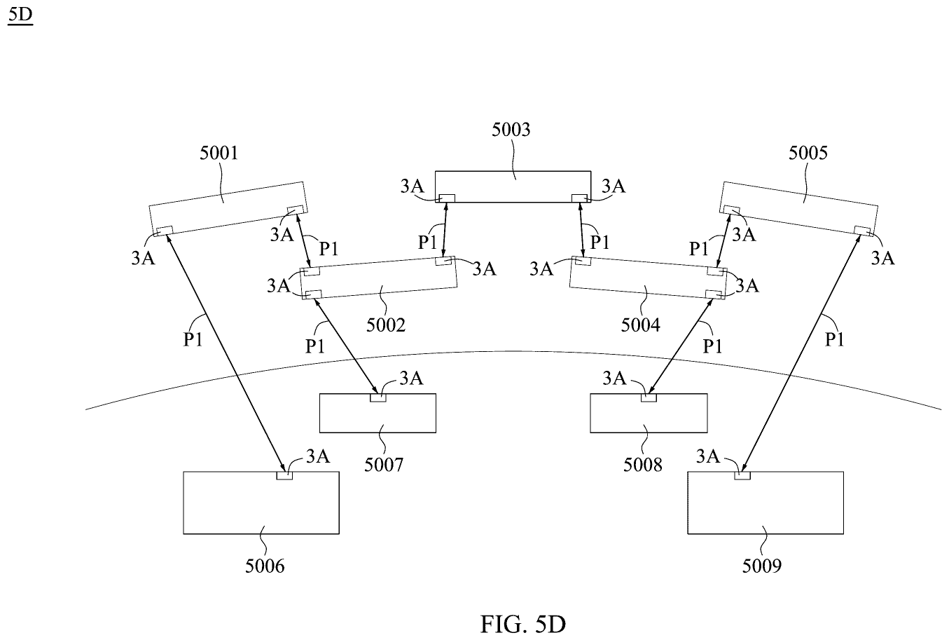

FIG. 5A is a top view of an electronic device 5A in accordance with some arrangements of the present disclosure. The electronic device 5A may include package structures 2A and 3A. The package structures 2A and 3A may be referred to as processing units. The electronic device 5A may be or include a data processing center including a great number of processing units with relatively long distances between the processing units.

In some arrangements, the transmission modules 300 of the package structures 2A and 3A substantially face each other. In some arrangements, the power path V1 and the thermal channel T1 may be non-parallel to the transmission path P1 for optical wireless communication. In some arrangements, bottom surfaces of the package structures 2A and 3A with the transmission modules 300 exposed are disposed facing each other rather than facing downwards.

According to some arrangements of the present disclosure, the package structures are optically communicated to each other through optical wireless communication. As such, arrangements of wiring structures between the packages can be omitted. Therefore, the space within a data processing center can be free of wiring structures (e.g. cables or optical fibers that connect the package structures), thus the arrangements of the package structures can be more flexible, and more package structures can be disposed within a data processing center.

FIG. 5B is a top view of an electronic device 5B in accordance with some arrangements of the present disclosure. The electronic device 5B may include package structures 3A and 4A. The package structures 3A and 4A may be referred to as processing units. The electronic device 5B may be or include a data processing center including a great number of processing units with relatively long distances between the processing units.

In some arrangements, the transmission modules 300 of the package structures 3A face the transmission modules 300 of the package structures 4A. In some arrangements, one of the package structures 4A overlap two of the package structures 3A.

FIG. 5C is a top view of an electronic device 5C in accordance with some arrangements of the present disclosure. The electronic device 5C may include package structures 2A, 3A, and 4A. The package structures 2A, 3A, and 4A may be referred to as processing units. The electronic device 5C may be or include a data processing center including a great number of processing units with relatively long distances between the processing units.

In some arrangements, the transmission modules 300 of the package structures 2A substantially face each other. In some arrangements, the transmission modules 300 of the package structures 3A face the transmission modules 300 of the package structures 4A.

FIG. 5D is a top view of a system 5D including an electronic device in accordance with some arrangements of the present disclosure.

The system 5D may include one or more electronic devices which include package structures 3A. The package structures 3A may be referred to as processing units. The system 5D may include a great number of processing units with relatively long distances between the processing units. In some arrangements, each of the package structures 3A may be a portion of or included in each of low earth orbit (LEO) satellites (LEO satellites 5001, 5002, 5003, 5004, and 5005) in space, enabling wireless communication between the LEO satellites in space. In some arrangements, each of the package structures 3A may be a portion of or included in each of receivers (e.g., receivers 5006, 5007, 5008, and 5009) of ground-based receiving stations on earth, enabling wireless communication between the LEO satellites in space and the receivers on earth. Compared to the signal loss of wireless transmission that occurs when propagating through the air, the space environment can reduce signal loss of wireless transmission. In some arrangements, the electronic devices of the system 5D may include package structures 2A, 3A, and/or 4A. The package structures 2A, 3A, and 4A may be referred to as processing units.

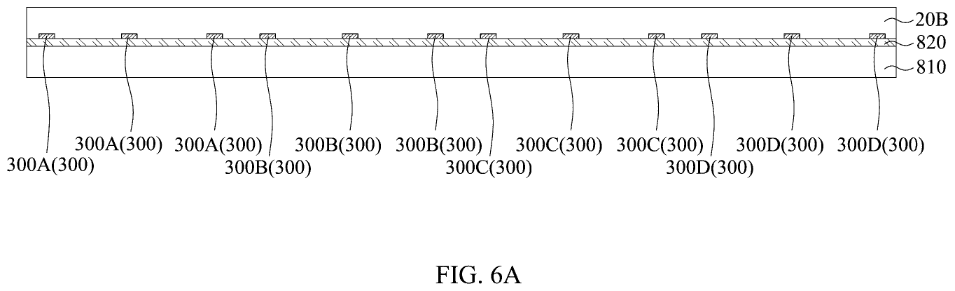

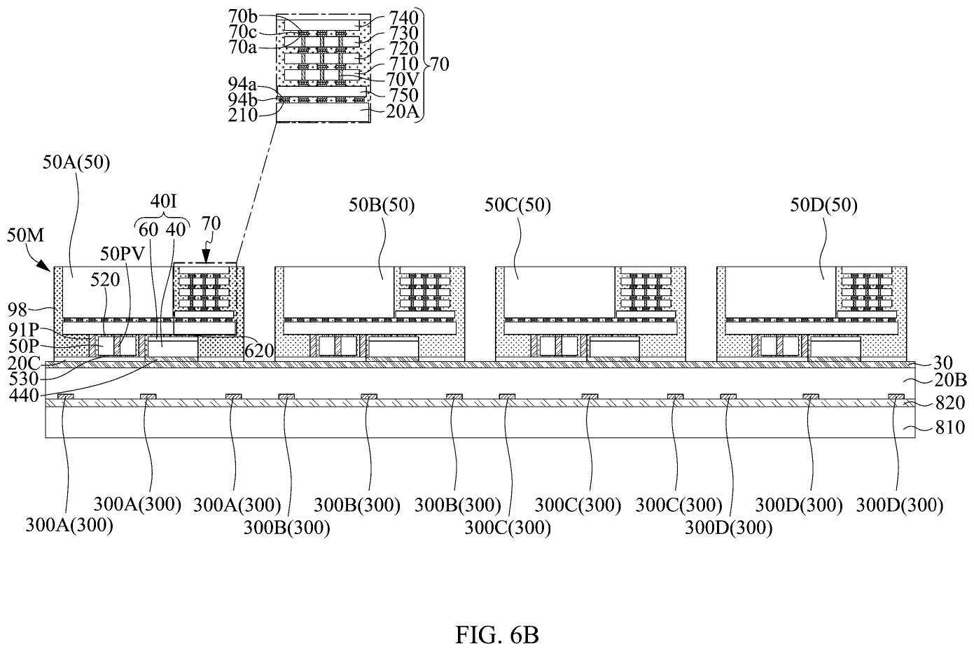

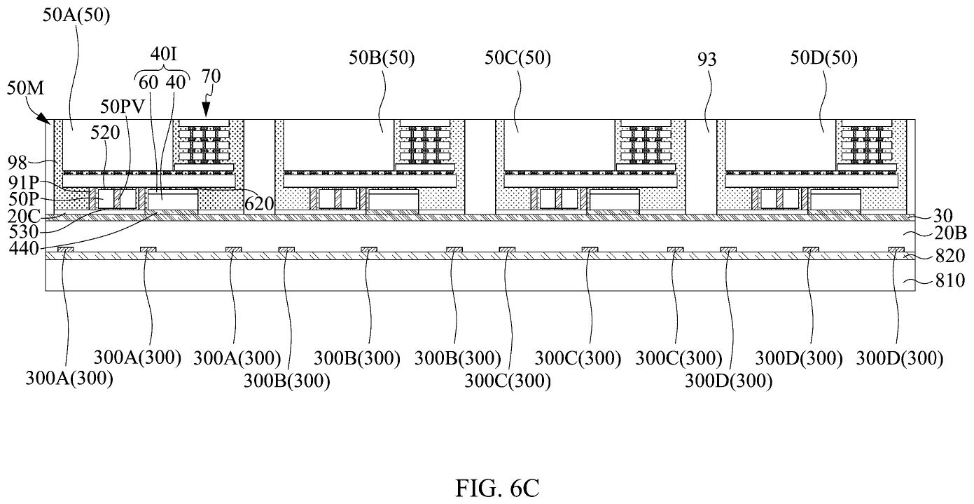

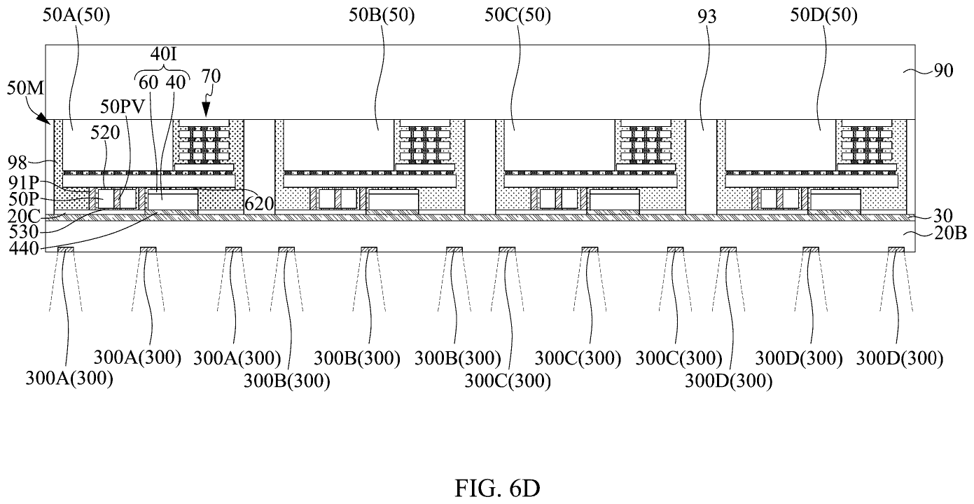

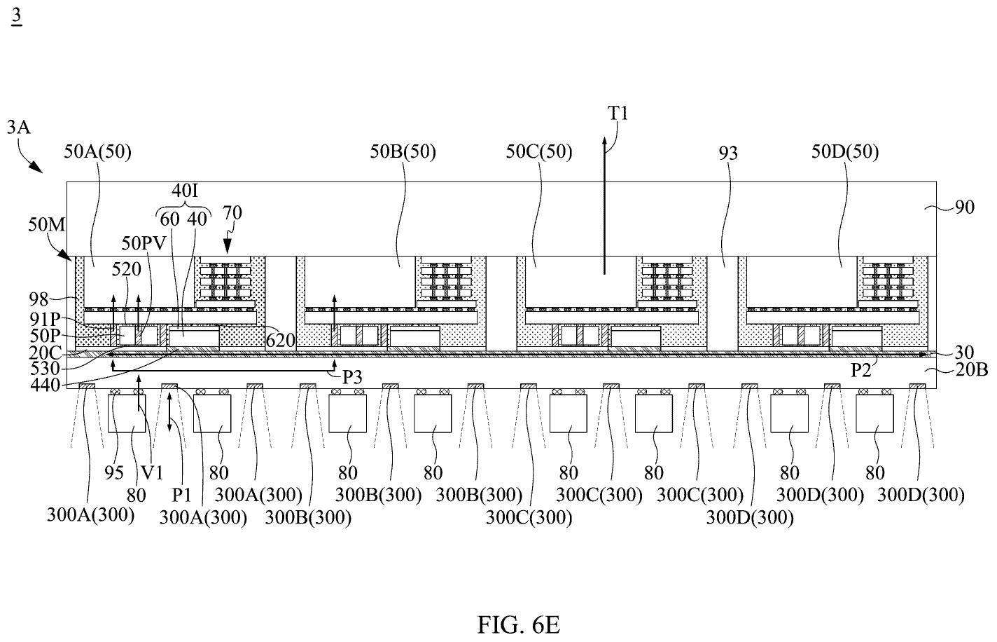

FIG. 6A, FIG. 6B, FIG. 6C, FIG. 6D, and FIG. 6E illustrate various stages of an exemplary method for manufacturing an electronic device 3 in accordance with some embodiments of the present disclosure.

Referring to FIG. 6A, a carrier 810 may be provided, and a circuit 20B may be disposed on the carrier 810 through an adhesive layer 820. In some arrangements, the adhesive layer 820 may be or include a die attach film (DAF). In some arrangements, the circuit 20B may include a dielectric layer, a conductive structure (not shown in FIG. 6A) formed in the dielectric layer, and transmission modules 300 (e.g., transmission modules 300A, 300B, 300C, and 300D) formed in the dielectric layer and exposed to the adhesive layer 820. The conductive structure in the circuit 20B may be or include an RDL. The transmission module 300 may include an optical source 310, an optical splitter 320, an optical phase shifter 330, and an optical grating 340, as illustrated in FIG. 1A.

Referring to FIG. 6B, a circuit 30 (e.g., an optical waveguide) may be formed on or embedded in the circuit 20B, and processing modules 50M may be disposed over the circuit 30. In some arrangements, the processing module 50M includes circuits 20A and 20C, a bridge component 40I, electronic components 50 and 50P, a storage component 70, at least a pillar 91P, and an encapsulant 98. The processing modules 50M may be manufactured and tested to ensure its functionality before being disposed over the circuit 30.

Referring to FIG. 6C, the processing modules 50M may be encapsulated by an encapsulant 93. In some arrangements, an encapsulant material may cover the processing modules 50M, and then a planarization operation (e.g., a CMP operation) may be performed to partially remove the encapsulant material to expose the electronic component 50 and the storage component 70 and form the encapsulant 93. The encapsulants 93 and 98 may independently include an epoxy resin having fillers dispersed therein, a molding compound (e.g., an epoxy molding compound or other molding compound), polyimide (PI), a phenolic compound or material, a polymer material with silicone dispersed therein, or a combination thereof.

Referring to FIG. 6D, a cooling device 90 may be disposed over the encapsulant 93 and the processing modules 50M. In some arrangements, the cooling device 90 contacts the electronic components 50 (e.g., the electronic components 50A, 50B, 50C, and 50D) of the processing modules 50M and the storage components 70.

Referring to FIG. 6E, power units 80 may be disposed on a bottom surface of the circuit 20B. In some arrangements, the transmission modules 300 are between and exposed by the power units 80. As such, the electronic device 3 may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a plurality of first processing units disposed in a data processing center; and
a first transmission module configured to adjust an optical transmission direction to communicate one of the first processing units with a second processing unit through optical wireless communication.

2. The electronic device as claimed in claim 1, further comprising a carrier, wherein the first processing units and the first transmission module are at opposite sides of the carrier.

3. The electronic device as claimed in claim 2, further comprising a thermal channel configured to transfer heat in a heat dissipation direction from the carrier toward the first processing units.

4. The electronic device as claimed in claim 3, wherein the optical transmission direction is substantially parallel to the heat dissipation direction.

5. The electronic device as claimed in claim 1, wherein the first transmission module comprises an optical phase array unit configured to receive or transmit an optical signal.

6. The electronic device as claimed in claim 1, wherein the first transmission module is configured to adjust a transmission direction of an optical signal transmitted to the second processing unit.

7. The electronic device as claimed in claim 1, wherein the one of the first processing units comprises a processing chip, a storage module, and a circuit layer electrically connecting the processing chip to the storage module.

8. The electronic device as claimed in claim 7, wherein the one of the first processing units further comprises a bridge element configured to provide electrical communication between the processing chip and the storage module through the circuit layer.

9. The electronic device as claimed in claim 1, further comprising a carrier which comprises an optical channel configured to provide signal transmission between at least two of the plurality of first processing units.

10. The electronic device as claimed in claim 1, further comprising a carrier and a plurality of power units configured to transmit power to the corresponding first processing units, wherein the plurality of power units and the plurality of first processing units are located at opposite surfaces of the carrier.

11. The electronic device as claimed in claim 10, wherein the first transmission module is between at least two of the plurality of power units.

12. The electronic device as claimed in claim 1, further comprising a second transmission module configured to receive an optical signal from the first transmission module through the optical wireless communication and transmit the optical signal to the second processing unit.

13. An electronic device, comprising:
a plurality of processing units; and
a circuit structure comprising an optical channel configured to transmit a first signal between at least two of the processing units and a transmission module configured to transmit a second signal through optical wireless communication.

14. The electronic device as claimed in claim 13, wherein the processing units constitute a processing array, and the transmission module is configured to transmit the second signal outwardly from the processing array through the optical wireless communication.

15. The electronic device as claimed in claim 13, wherein the optical channel is configured to transmit the first signal in a first direction, and the transmission module is configured to transmit the second signal in a second direction different from the first direction.

16. The electronic device as claimed in claim 15, wherein the first direction is substantially perpendicular to the second direction.

17. An electronic device, comprising:
a carrier having a first surface and a second surface opposite to the first surface;
a plurality of electronic components supported by the first surface; and
a plurality of transmission modules exposed from the second surface and configured to transmit a first optical signal outwardly from the electronic components through optical wireless communication.

18. The electronic device as claimed in claim 17, further comprising a plurality of power units disposed over the second surface, wherein the plurality of transmission modules are exposed by the plurality of power units.

19. The electronic device as claimed in claim 18, wherein the plurality of transmission modules comprise a plurality of circuits in the carrier and a plurality of light emitting areas exposed by the second surface.

20. The electronic device as claimed in claim 19, wherein the plurality of light emitting areas of the plurality of transmission modules are between the plurality of power units.
